(19) United States
(12) Patent Application Publication
(10) Pub. No.: US 2025/0174497 A1
(43) Pub. Date: May 29, 2025

(54) Die-Level Parametric Prediction Boosting Method and System for Improving Prediction Accuracy by Incorporating Physical Location Parametric Data

(71) Applicant: MEDIATEK INC., Hsinchu City (TW)

(72) Inventors: Chin-Wei Lin, Hsinchu City (TW); Po-Chao Tsao, Hsinchu City (TW); Yu-Lin Yang, Hsinchu City (TW); Cheng-Tien Wan, Hsinchu City (TW); Tung-Hsing Lee, Hsinchu City (TW); Chung-Kai Chang, Hsinchu City (TW); Yi-Ju Ting, Hsinchu City (TW); Chia-Jung Ni, Hsinchu City (TW); Chia-Chun Sun, Hsinchu City (TW); Cheng-Chien Huang, Hsinchu City (TW); Yun-San Huang, Hsinchu City (TW); Ming-Cheng Lee, Hsinchu City (TW)

(73) Assignee: MEDIATEK INC., Hsinchu City (TW)

(21) Appl. No.: 18/948,412

(22) Filed: Nov. 14, 2024

Related U.S. Application Data
(60) Provisional application No. 63/603,676, filed on Nov. 29, 2023.

(51) Int. Cl. H01L 21/66; H01L 21/67

(52) U.S. Cl. CPC H01L 22/14; H01L 21/67259; H01L 22/12; H01L 22/34

(57) ABSTRACT

A die-level parametric prediction boosting method includes acquiring a wafer map having a plurality of dies, selecting a die from the plurality of dies, inputting physical location parametric data of the die and a plurality of electrical parametric features of the die to a training model, and generating predicted data of the die by the training model according to the physical location parametric data and the plurality of electrical parametric features.

### CROSS REFERENCE TO RELATED APPLICATIONS

This application claims the benefit of U.S. Provisional Application No. 63/603,676, filed on Nov. 29, 2023. The content of the application is incorporated herein by reference.

### BACKGROUND

With the rapid advancement of technologies, various chips and integrated circuits (ICs) are adopted in our daily life. Therefore, high quality and low operational risk ICs are required for various electronic applications. In a silicon testing flow, to provide high quality and low operational risk ICs, outlier ICs are identified and labeled by analyzing measured testing data.

However, in a conventional outlier IC identification method, some outlier ICs can be identified according to their measured testing data. It should be understood that different ICs have different electrical parametric features. Since electrical parametric features are varied for different ICs, when no additional information of the ICs is introduced, it is hard to generate accurate predicted data of the different ICs according to the electrical parametric features.

Therefore, developing a parametric prediction system capable of boosting prediction accuracy is an important design issue.

### SUMMARY

In an embodiment of the present invention, a die-level parametric prediction boosting method is disclosed. The die-level parametric prediction boosting method comprises acquiring a wafer map comprising a plurality of dies, selecting a die from the plurality of dies, inputting physical location parametric data of the die and a plurality of electrical parametric features of the die to a training model, and generating predicted data of the die by the training model according to the physical location parametric data and the plurality of electrical parametric features.

In another embodiment of the present invention, a die-level parametric prediction boosting system is disclosed. The die-level parametric prediction boosting system comprises a mass production data source and a training model. The training model is coupled to the mass production data source. After a wafer map comprising a plurality of dies is acquired from the mass production data source, a die is selected from the plurality of dies. Physical location parametric data of the die and a plurality of electrical parametric features of the die are inputted to the training model. The training model generates predicted data of the die according to the physical location parametric data and the plurality of electrical parametric features.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a die-level parametric prediction boosting system according to an embodiment of the present invention.

FIG. 2 is an illustration of physical features of a wafer map of the die-level parametric prediction boosting system in FIG. 1

FIG. 3 is a flow chart of performing a die-level parametric prediction boosting method by the die-level parametric prediction boosting system in FIG. 1.

### DETAILED DESCRIPTION

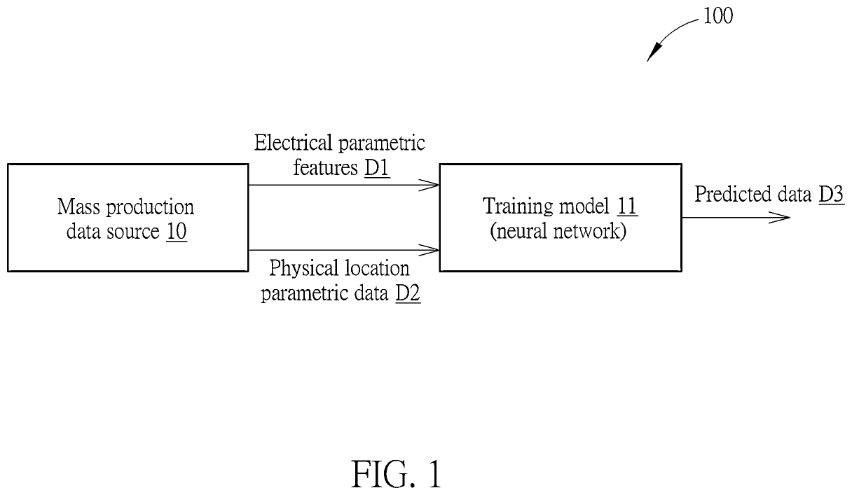

FIG. 1 is a block diagram of a die-level parametric prediction boosting system 100 according to an embodiment of the present invention. The die-level parametric prediction boosting system 100 includes a mass production data source 10 and a training model 11. The training model 11 is coupled to the mass production data source 10. The mass production data source 10 can be at least one stage node of a wafer testing line. For example, the mass production data source 10 can be a chip probe (CP) stage node or a final test (FT) stage node. The CP stage node or the FT stage node can provide the mass production data. In another embodiment, the mass production data source 10 can be the CP stage node and the FT stage node of the wafer testing line. The CP stage node and the FT stage node can jointly provide the mass production data. The training model 11 can embody a neural network architecture. Thus, the training model 11 can perform a process related to deep learning or machine learning. In the die-level parametric prediction boosting system 100, after a wafer map including a plurality of dies is acquired from the mass production data source 10, a die is selected from the plurality of dies. The wafer map can be pre-defined according to mass production data acquired from the mass production data source 10. Then, the physical location parametric data D2 of the die and a plurality of electrical parametric features D1 of the die are inputted to the training model 11. Finally, the training model 11 can generate (or say, infer) predicted data D3 of the die according to the physical location parametric data D2 and the plurality of electrical parametric features D1. Details of performing the die-level parametric prediction boosting method are illustrated below.

In the die-level parametric prediction boosting system 100, the training model 11 can acquire the plurality of electrical parametric features of the die according to the mass production data. Specifically, the plurality of electrical parametric features of the die can include a chip speed, a chip power leakage, or a chip minimum voltage measured by a sensor or a detector embedded in the die. For example, N electrical parametric features of an i-th die of the wafer map can be inputted to the training model 11. The N electrical parametric features (as shown in D1 of FIG. 1) of the i-th die of the wafer map can be expressed as Table T1.

TABLE T1

| | |
|---|---|
| index n = 1 | electrical parametric feature-1 (i) |
| index n = 2 | electrical parametric feature-2 (i) |
| . | . |
| . | . |
| . | . |
| index n = N | electrical parametric feature-N (i) |

N is a positive integer. Therefore, when M dies are selected, the N×M electrical parametric features can be inputted to the training model 11 for inferring the predicted data D3. Here, distributions of the M dies on the wafer map can be arbitrary. M is a positive integer. In the die-level parametric prediction boosting system 100, the predicted data D3 of the die can include an ON/OFF current, a threshold voltage, or channel information of metal-oxide-semiconductor field-effect transistors (MOSFETs). Any hardware of technology modification falls into the scope of the present invention.

As previously mentioned, the training model 11 can embody the neural network architecture. Therefore, the training model 11 should be fully trained before the training model 11 infers the predicted data D3. In an embodiment, die training data can be acquired from the CP stage node or the FT stage node. The training model 11 can include information of pre-trained electrical features in each die of the wafer map. Then, after the die training data is acquired, the training model 11 can be established according to the die training data. Then, die validation data can be used for determining if the training model 11 is fully trained. When the training model 11 is not fully trained, the training model 11 is re-trained or continuously trained according to the die training data. When the training model 11 is fully trained, the training model 11 is outputted as a finalized training model for generating the predicted data D3. In the embodiment, the training model 11 can be implemented by using any neural network architecture, such as a convolutional neural network (CNN) or a recurrent neural network (RNN).

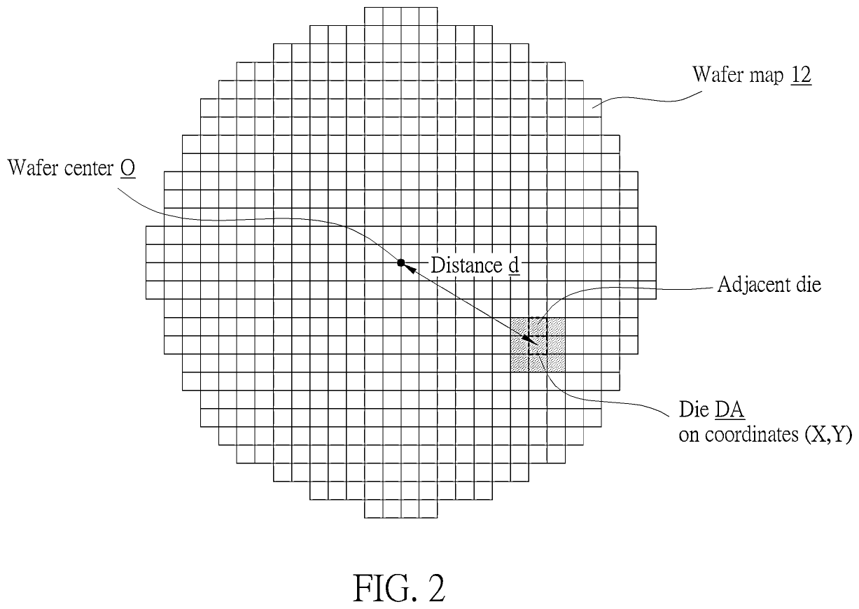

FIG. 2 is an illustration of physical features of the wafer map 12 of the die-level parametric prediction boosting system 100. The wafer map 12 can be viewed as a discrete map of dies with a substantially circular boundary. A wafer center O is marked as the center of the circular wafer map 12. The die DA is selected from the plurality of dies of the wafer map 12. Coordinates of the center of the die DA are denoted as (X, Y). The distance from the center of the die DA to the wafer center O is denoted as d. In the embodiment, the physical location parametric data D2 of the die DA can include coordinates (X, Y) of the center of the die DA on the wafer map 12, and the distance d from the center of the die DA to the wafer center O. As previously mentioned, the training model 11 can include the information of pre-trained electrical features in each die of the wafer map 12. Therefore, when the physical location parametric data D2 of the die DA is inputted to the training model 11, the physical location parametric data D2 can be used for assisting the training model 11 to infer the accurate predicted data D3. However, any technology modification falls into the scope of the present invention. For example, in another embodiment, information of the wafer center O is pre-configured in the training model 11. Therefore, when the coordinates (X, Y) of the center of the die DA are inputted to the training model 11, the distance d from the center of the die DA to the wafer center O can be derived as \sqrt{(X−α)²−(X−b)²}. Here, coordinates of the wafer center O are expressed as (a, b). In another embodiment, the physical location parametric data D2 of the die DA can further include electrical variations of dies adjacent to the die DA. In other words, features of “adjacent” dies can be used for enhancing the prediction accuracy of inferring the predicted data D3 since physical or electrical distributions of the die DA and “adjacent” dies are similar. After the predicted data D3 is inferred by the training model 11, the predicted data D3 can be used for simplifying subsequent testing processes. Further, after the predicted data D3 is inferred by the training model 11, the neural network can use the training model 11 for identifying outlier dies of the plurality of dies according to the predicted data.

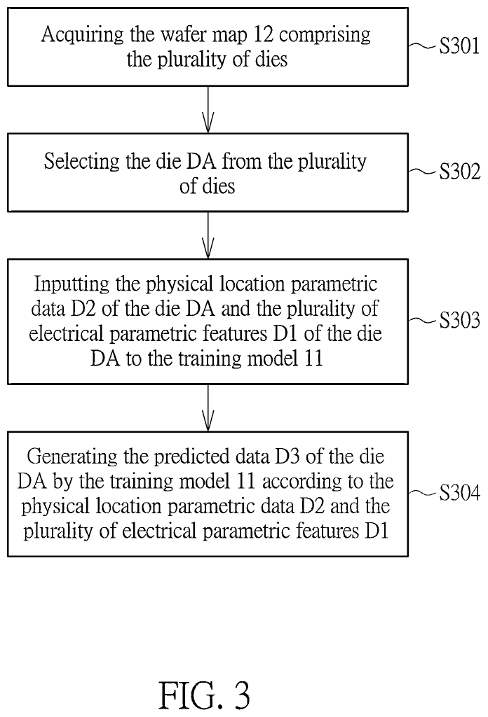

FIG. 3 is a flow chart of performing a die-level parametric prediction boosting method by the die-level parametric prediction boosting system 100. The die-level parametric prediction boosting method includes step S301 to step S304. Any technology or hardware modification falls into the scope of the present invention. Step S301 to step S304 are illustrated below.
step S301: acquiring the wafer map 12 comprising the plurality of dies;
step S302: selecting the die DA from the plurality of dies;
step S303: inputting the physical location parametric data D2 of the die DA and the plurality of electrical parametric features D1 of the die DA to the training model 11;
step S304: generating the predicted data D3 of the die DA by the training model 11 according to the physical location parametric data D2 and the plurality of electrical parametric features D1.

Details of step S301 to step S304 are previously illustrated. Thus, they are omitted here. In the die-level parametric prediction boosting system 100, the physical location parametric data D2 in conjunction with the plurality of electrical parametric features D1 of the die DA are used for enhancing the prediction accuracy of inferring the predicted data D3 by the training model 11. Particularly, the physical location parametric data D2 can include the coordinates (X, Y) of the center of the die DA and the distance d from the center of the die DA to the wafer center O. Therefore, additional data amount and additional computational for enhancing the prediction accuracy of inferring the predicted data D3 can be minimized.

To sum up, the present invention discloses a die-level parametric prediction boosting method and a die-level parametric prediction boosting system. The die-level parametric prediction boosting system can combine the physical location parametric data with the plurality of electrical parametric features for inferring the predicted data. Although the use of electrical parametric features may complicate achieving high prediction accuracy when inferring the predicted data, the physical location parametric data can aid the training model in making highly accurate predictions.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A die-level parametric prediction boosting method comprising:
acquiring a wafer map comprising a plurality of dies;
selecting a die from the plurality of dies;
inputting physical location parametric data of the die and a plurality of electrical parametric features of the die to a training model; and
generating predicted data of the die by the training model according to the physical location parametric data and the plurality of electrical parametric features.

2. The method in claim 1, further comprising:
acquiring mass production data of the plurality of dies from a chip probe (CP) stage node and/or a final test (FT) stage node;
wherein the wafer map is defined according to the mass production data.

3. The method in claim 2, further comprising:
acquiring the plurality of electrical parametric features of the die according to the mass production data;
wherein the plurality of electrical parametric features of the die comprise a chip speed, a chip power leakage, or a chip minimum voltage measured by a sensor or a detector embedded in the die.

4. The method in claim 1, wherein the predicted data of the die comprises an ON/OFF current, a threshold voltage, or channel information of metal-oxide-semiconductor field-effect transistors (MOS FETs).

5. The method in claim 1, further comprising:
acquiring die training data;
establishing the training model according to the die training data;
wherein the training model comprises information of pre-trained electrical features in each die of the wafer map.

6. The method in claim 5, further comprising:
when the training model is not fully trained, re-training the training model according to the die training data.

7. The method in claim 5, further comprising:
when the training model is fully trained, outputting the training model as a finalized training model for generating the predicted data.

8. The method in claim 1, wherein the physical location parametric data of the die comprises coordinates of a center of the die on the wafer map, and a distance from the center of the die to a wafer center.

9. The method in claim 8, wherein the physical location parametric data of the die on the wafer map further comprises electrical variations of dies adjacent to the die.

10. The method in claim 1, further comprising:
identifying at least one outlier die of the plurality of dies according to the predicted data.

11. A die-level parametric prediction boosting system comprising:
a mass production data source; and
a training model coupled to the mass production data source;
wherein after a wafer map comprising a plurality of dies is acquired from the mass production data source, a die is selected from the plurality of dies, physical location parametric data of the die and a plurality of electrical parametric features of the die are inputted to the training model, and the training model generates predicted data of the die according to the physical location parametric data and the plurality of electrical parametric features.

12. The system in claim 11, wherein the wafer map is defined according to mass production data acquired from the mass production data source, and the mass production data source comprises a chip probe (CP) stage node and/or a final test (FT) stage node.

13. The system in claim 12, wherein the training model acquires the plurality of electrical parametric features of the die according to the mass production data, and the plurality of electrical parametric features of the die comprise a chip speed, a chip power leakage, or a chip minimum voltage measured by a sensor or a detector embedded in the die.

14. The system in claim 11, wherein the predicted data of the die comprises an ON/OFF current, a threshold voltage, or channel information of metal-oxide-semiconductor field-effect transistors (MOS FETs).

15. The system in claim 11, wherein after die training data is acquired, the training model is established according to the die training data, and the training model comprises information of pre-trained electrical features in each die of the wafer map.

16. The system in claim 15, wherein when the training model is not fully trained, the training model is re-trained according to the die training data.

17. The system in claim 15, wherein when the training model is fully trained, the training model is outputted as a finalized training model for generating the predicted data.

18. The system in claim 11, wherein the physical location parametric data of the die comprises coordinates of a center of the die on the wafer map, and a distance from the center of the die to a wafer center.

19. The system in claim 18, wherein the physical location parametric data of the die on the wafer map further comprises electrical variations of dies adjacent to the die.

20. The system in claim 11, wherein the training model identifies at least one outlier die of the plurality of dies according to the predicted data.
